(19) United States
(12) Patent Application Publication
(10) Pub. No.: US 2003/0131469 A1
(43) Pub. Date: Jul. 17, 2003

(54) Method of manufacturing an electrode for a plasma reactor and an electrode

(76) Inventors: Sjoerd Van Den Cruijsem, Helmond (NL); Robertus Jacobus Van Leeuwen, Eindhoven (NL); Marcel Maria Michorius, Eindhoven (NL)

Correspondence Address: MacPherson Kwok, Chen & Heid, Suite 195E, 2001 Gateway Place, San Jose, CA, 95110, US

(21) Appl. No.: 10/168,870

(22) PCT Filed: Dec. 22, 2000
(86) PCT No.: PCT/NL00/00951

(30) Foreign Application Priority Data
Dec. 24, 1999 (NL) 1013954

(51) Int. Cl. H05K 3/20; H05K 3/02; H01B 5/00

(52) U.S. Cl. 29/825; 29/831; 29/846; 29/521; 174/126.1

(57) ABSTRACT

The invention relates to a method for manufacturing an electrode for a plasma reactor, comprising the step of interconnecting a support ring and an electrode plate provided with through holes mechanically and electrically by means of a shrink connection, wherein the connecting step furthermore comprises the application of an electrically conductive layer to the joining interface between the electrode plate and the support ring. Furthermore an electrode is provided, wherein said support ring and said electrode include interlocking parts, to the joining surface at which the electrically conductive layer is applied.

The invention relates to a method of manufacturing an electrode for a plasma reactor, comprising the step of interconnecting a support ring and an electrode plate provided with through holes mechanically and electrically by means of a shrink connection.

A method and an electrode of this kind are known from U.S. Pat. No. 5,674,367.

With the prior art electrode the support ring and the electrode plate are mechanically interconnected by means of a shrink connection. The electrical contact between the electrode and the electrode plate is thereby provided by the abutting parts thereof at the joining interface between these parts.

In particular the electrical contact resistance between the electrode and the electrode plate of the prior art electrode is capable of improvement.

The object of the invention is to improve the prior art method and electrode to such an extent that this will result in an electrode exhibiting a considerably reduced electrical contact resistance between the electrode plate and the support ring.

In order to accomplish that objective, the invention provides a method of the kind referred to in the introduction, which is characterized in that the connecting step furthermore comprises the application of an electrically conductive layer to the joining interface between the electrode plate and the support ring.

Carrying out the shrink connecting step in combination with the use of the electrically conductive layer makes it possible to reduce the electrical resistance between the electrode plate and the support ring by a factor of 1000.

In accordance with the invention the electrically conductive layer can be applied to at least one of the support ring and the electrode before the two are interconnected.

In yet another embodiment of the invention the electrically conductive layer can be applied after the electrode plate and the support ring have been interconnected.

The conductive layer may preferably consist of a conductive paste, such as a silver paste, carbon paste or nickel paste.

In the preferred embodiment of the invention the electrically conductive layer is formed of a heat resistant composition, such that the layer will not become detached, form particles or peel off at the temperatures that are used in a plasma reactor.

The support ring and the electrode plate may include interlocking parts, wherein the electrically conductive layer is applied to either one of said parts, or to both, preferably in the corner areas of the interlocking parts.

If a graphite ring is used as the support ring, a graphite having a high coefficient of thermal expansion is used for the graphite ring. The electrode plate may be a silicon plate.

In an embodiment of the electrode the support ring includes an upright annular portion, and the electrode plate includes an upright central portion, wherein the upright central portion of the electrode is mounted in the upright annular portion of the support ring with a proper fit.

In yet another embodiment of the electrode according to the invention the support ring includes an upright annular portion and the electrode plate is made in the form of a disc, which rests on the upright annular portion of the support ring.

In the preferred embodiment the connecting step comprises a mechanical locking step, wherein a flange and a recess interlock. The shrink connecting step and the locking step are preferably carried out simultaneously.

In an embodiment the shrink connecting step comprises the steps of heating the support ring, placing the electrode plate in or on the support ring and cooling the support ring.

In embodiments of the electrode according to the invention the electrode plate has a flange formed on the outer circumference thereof, and the upright annular portion of the support ring has a recess formed in the inner circumference thereof, or the upright annular portion of the support ring has a flange formed on the outer circumference thereof and the electrode plate has a recess formed in the inner circumference thereof, wherein the outer circumference flange and the inner circumference recess are in engagement with each other.

The electrically conductive layer is preferably positioned adjacently to the inner circumference recess and the outer circumference flange.

The invention will now be explained in more detail with reference to the drawings, wherein:

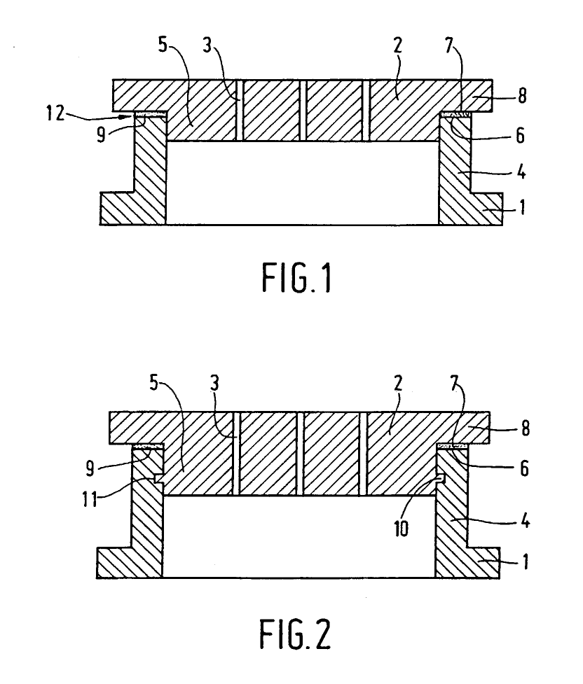

FIG. 1 is a schematic, sectional view of a first embodiment of an electrode according to the invention.

FIG. 2 is a schematic, sectional view of a second embodiment of the present invention.

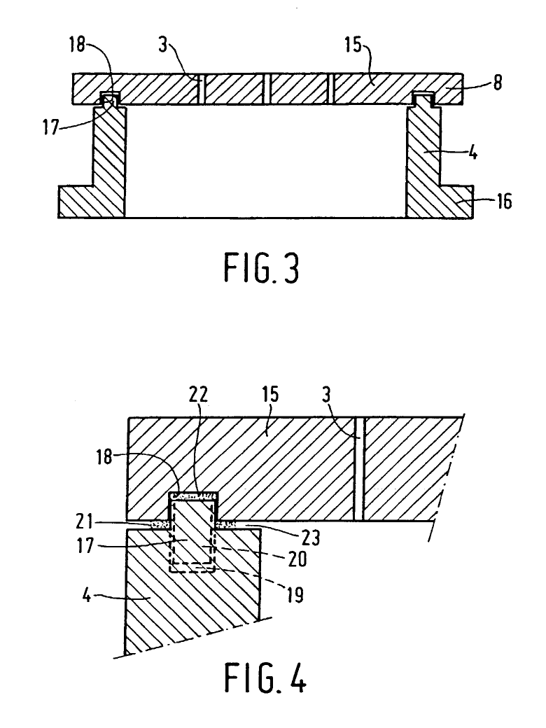

FIG. 3 is a schematic, sectional view of a third embodiment of the present invention.

FIG. 4 is a larger-scale schematic view of a part of the third embodiment of FIG. 3.

In a plasma reactor of for example certain semiconductor production apparatus an electrode that is called a “shower head” in the English-speaking regions is used. The electrode consists of a graphite ring, on which a silicon plate provided with a hole pattern is disposed. The whole is clamped down in the plasma reactor and functions as an electrode in the plasma process to be carried out. A gas is passed over an underlying silicon wafer via the hole pattern, and the ionized gas removes a layer from the silicon wafer. The electrode has to meet a number of requirements. Besides being resistant to the process gases that are used, it must exhibit proper electric conductivity in order to be able to function as an electrode. In addition to that, the mechanical connection or adherence between the graphite ring and the silicon plate must be very good in order to minimize the electrical contact resistance and to prevent the silicon plate becoming detached from the graphite ring.

In accordance with the present invention the mechanical connection is effected by means of a so-called shrink fit. A type of graphite having a high coefficient of thermal expansion is used thereby. The dimensions of the graphite ring are such that a silicon plate having a shape adapted thereto can be shrunk fit therein. The graphite ring is thereby heated to a high temperature (for example 450° C.-550° C.), the silicon plate is placed into the graphite ring and the whole is cooled, which provides a very adequately connected electrode. It is also possible to shrink fit the graphite ring in the silicon plate.

A further improvement can be achieved by adapting the graphite ring and by further adapting the silicon plate. Adaptation of the silicon plate and the graphite ring leads to a further improved mechanical connection as a result of what is called “mechanical interlocking” in the English-speaking regions.

In both cases the shrink fit temperature is well above the application temperatures, so that the silicon plate and the graphite ring will not become detached from each other in use.

The dimensions of the graphite ring are such that after the shrink fit has been effected, the underside of the graphite ring will be parallel to the surface of the silicon plate.

In addition to the mechanical connection, also an electrical connection is effected by means of the shrink fit. In accordance with the invention, a further improvement is realised by applying an electrically conductive layer to the joining surface between the silicon plate and the graphite ring prior to and/or after completion of the shrink fit. The application of a conductive layer that is resistant to the process gases makes it possible to enhance the electrical resistance by a factor of 1000. The composition of the conductive layer has to be selected such that it will not influence the process, that it will not generate any particles and that it will be capable of resisting the application temperature, that is, the temperature that prevails in the plasma reactor during operation thereof. For example, the conductive layer may be a conductive paste, such as a silver paste, a carbon paste or a nickel paste. The application of the conductive layer must take place in such a manner that the adhesion of the conductive layer will not be at risk, with the conductive layer becoming detached, forming particles or peeling off. The application may take place by means of an injection system or an airbrush system, for example.

In FIGS. 1 and 2, reference numerals 1 and 2 indicate a support ring and an electrode plate, respectively. Electrode plate 2 is provided with through holes 3. Support ring 1 and electrode plate 2 are mechanically and electrically connected so as to form an electrode for a plasma reactor. Support ring 1 and electrode plate 2 of FIGS. 1 and 2 are mechanically and electrically connected by means of a shrink connection (shrink fit). In FIG. 2 a mechanical locking engagement is moreover used, which can be effected at the same time as the shrink connection.

Advantageously, an electrically conductive layer 9 can be applied in the corner 12 between electrode plate 2 and support ring 1.

The shrink connecting step may comprise the steps of heating the support ring 1, placing the electrode plate 2 into the support ring 1 and cooling the support ring 1.

A material having a high coefficient of thermal expansion is used for the support ring 1. The material of the support ring may be graphite, and the material of the electrode plate 2 may be silicon.

As is shown in FIGS. 1 and 2, the electrode of a plasma reactor comprises a support ring 2 and an electrode plate 2 provided with through holes 3, which are mechanically and electrically connected, wherein support ring 1 includes an upright annular portion 4. Unlike the conventional electrode, electrode plate 2 furthermore includes an upright central portion 5, and this upright central portion 5 of electrode plate 2 is mounted in upright annular portion 4 of support ring 1 with a proper fit.

As is furthermore shown in FIGS. 1 and 2, the free upper surface 6 of upright annular portion 4 of support ring 1 is parallel to the surface 7 of an annular portion 8 of electrode plate 8 surrounding upright central portion 5.

Preferably, the surface 7 of annular portion 8 of electrode plate 2 surrounding upright central portion 5 that is in contact with the free surface 6 of upright annular portion 4 of support ring 1 is provided with an electrically conductive layer 9.

In the embodiment that is shown in FIG. 2, a flange 10 is formed on the outer circumference of upright central portion 5 of electrode plate 2, and a recess 11 is formed in the inner circumference of upright annular portion 4 of support ring 1, with the flange 10 and the recess 11 being in engagement with each other.

FIG. 3 shows a third embodiment of an electrode according to the invention, comprising an approximately disc-shaped electrode plate 15 provided with through holes 3, and a support ring 16 provided with an upright annular portion 4, wherein the electrode plate 15 rests on the annular portion 4.

In the embodiment that is shown in FIG. 3, the upright annular portion 4 of annular support 16 has a flange 17 formed on the outer circumference thereof, and the disc-shaped electrode plate 15 has a recess 18 formed in the inner circumference thereof, wherein the outer circumference flange 17 and the inner circumference recess 18 are in engagement with each other by means of a shrink connection.

FIG. 4 is a larger-scale view of the shrunk connected outer circumference flange 17 and the inner circumference recess 18 of the electrode that is shown in FIG. 3.

The electrically conductive layer can thereby extend between the opposing parts of electrode plate 15 and annular support 4, as indicated by numeral 21, or between the outer circumference flange 17 and the inner circumference recess 18, as indicated by numeral 22. Corner area 23 remains free from the conductive layer, such as a paste or the like.

A person who is skilled in the art will understand that the electrode plate 15 may be provided with a flange-shaped recess, which engages in an annular recess in the upright annular portion 4 of support ring 16, as is indicated in broken lines 19 and 20, respectively, in FIG. 4. The same applies, in a similar manner, to the embodiment of FIG. 2, wherein the upright annular portion 4 may include an outer circumference flange 10 and the electrode plate may include an associated inner circumference recess 10.

The operation of the electrode of FIGS. 1 and 2 in a plasma reactor is the same as that of the conventional electrode, and also the method of fitting the electrode of FIGS. 1 and 2 may be a conventional method.

1. A method of manufacturing an electrode for a plasma reactor, comprising the step of interconnecting a support ring (1; 16) and an electrode plate (2; 15) provided with through holes (3) mechanically and electrically by means of a shrink connection, characterized in that said connecting step furthermore comprises the application of an electrically conductive layer (9; 21; 22) to the joining interface between the electrode plate (2; 15) and the support ring (1; 16).

2. A method according to claim 1, characterized in that said electrically conductive layer (9; 21; 22) is applied to at least one of said support ring (1; 16) and said electrode (2; 15) before the two are interconnected.

3. A method according to claim 1 or 2, characterized in that said electrically conductive layer (9; 21; 22) is applied after the electrode plate (2; 15) and the support ring (1; 16) have been interconnected.

4. A method according to any of the preceding claims, characterized in that said conductive layer (9; 21; 22) consists of a conductive paste, such as a silver paste, carbon paste or nickel paste.

5. A method according to any of the preceding claims, characterized in that said conductive layer (9; 21; 22) is applied by means of an injection system or an airbrush system.

6. A method according to any of the preceding claims, characterized in that said electrically conductive layer (9; 21; 22) is formed of a heat resistant composition, such that said layer (9; 21; 22) will not become detached, form particles or peel off at temperatures that are used in a plasma reactor.

7. A method according to any of the preceding claims, characterized in that said support ring (1; 16) and said electrode plate (2; 15) include interlocking parts (10, 11; 17, 18; 19, 20), wherein said electrically conductive layer (9; 21; 22) is applied to either one of said parts, or to both.

8. A method according to claim 7, characterized in that said electrically conductive layer (9; 21; 22) is applied in corner areas of said interlocking parts (10, 11; 17, 18; 19, 20).

9. A method according to any of the preceding claims, characterized in that said connecting step comprises a mechanical locking step.

10. A method according to any of the preceding claims, characterized in that said mechanical locking step comprises the interlocking of a flange and a recess.

11. A method according to claims 9 and 10, characterized in that said shrink connecting step and said locking step are carried out simultaneously.

12. A method according to claim 9, 10 or 11, characterized in that said shrink connecting step comprises the steps of heating the support ring (1; 16), placing the electrode plate (1; 15) in the support ring (1; 16) and cooling the support ring (1; 16).

13. A method according to any of the preceding claims, characterized in that the support ring (1; 16) is a graphite ring and the electrode plate (1; 15) is a silicon plate, wherein a graphite having a high coefficient of thermal expansion is used for said graphite ring.

14. An electrode for a plasma reactor manufactured in accordance with a method according to any of the preceding claims.

15. An electrode according to claim 14, characterized in that the support ring (1) includes an upright annular portion (4), said upright annular portion (4) having an inner circumference, and the electrode plate (2) includes an upright central portion (5), said upright central portion (5) having an outer circumference, wherein the upright central portion (5) of the electrode plate (2) is mounted in the upright annular portion (4) of the support ring (1) with a proper fit.

16. An electrode according to claim 15, characterized in that the free surface of the upright annular portion (4) of the support ring (1) is parallel to the surface of the annular portion (8) of the electrode plate (2) that surrounds the surface of the upright central portion (5).

17. An electrode according to claim 15 or 16, characterized in that said electrically conductive layer (9) is applied to the joining interface (6, 7) between the upright annular portion (4) of the support ring (1) and the central portion (5) of the electrode plate (2).

18. An electrode according to claim 15, 16 or 17, characterized in that the upright annular portion (5) of the electrode plate (2) has a flange (10) formed on the outer circumference thereof, and the upright annular portion (4) of the support ring (1) has a recess (11) formed in the inner circumference thereof, wherein said flange (10) and said recess (11) are in engagement with each other.

19. An electrode according to claim 15, 16 or 17, characterized in that the upright central portion (5) of the electrode plate (2) has a recess formed in the outer circumference thereof, and the upright annular portion (4) of the support ring (1) has a flange formed on the inner circumference thereof, wherein said recess and said flange are in engagement with each other.

20. An electrode according to claim 14, characterized in that the support ring (16) includes an upright annular portion (4), said upright annular portion (4) having an outer circumference, and the electrode plate (15) is substantially disc-shaped, wherein the electrode plate (15) rests with a circumference thereof on the outer circumference of the upright annular portion (4) of the support ring (16).

21. An electrode according to claim 20, characterized in that the upright annular portion (4) of the support ring (16) has a flange (17) formed on the outer circumference thereof, and the disc-shaped electrode plate (15) has a recess (18) formed in said circumference with which the electrode plate rests on the support ring (16), wherein said flange (17) and said recess (18) are in engagement with each other.

22. An electrode according to claim 20, characterized in that the upright annular portion (4) of the support ring (15) has a recess (19) formed in the outer circumference thereof, and the disc-shaped electrode plate (15) has a flange (20) formed on said circumference with which the electrode plate rests on the support ring (16), wherein said recess (19) and said flange (20) are in engagement with each other.

23. An electrode according to claim 18, 19, 20 or 21, characterized in that said electrically conductive layer (21, 22) is present on or adjacently to said inner circumference recess (18; 19) and said outer circumference flange (17; 20).

24. A substantially disc-shaped electrode plate (2) arranged for use with a support ring (1) to form an electrode for a plasma reactor, said electrode plate (2) having through holes (3) and an upright central portion (5) having an outer circumference and a flange (10) formed on the Outer circumference for engaging a recess (11) formed in said support ring (1).

25. A substantially disc-shaped electrode plate (2) arranged for use with a support ring (1) to form an electrode for a plasma reactor, said electrode plate (2) having through holes (3) and an upright central portion (5) having an outer circumference and a recess formed in said outer circumference for engaging a flange formed in said support ring (1).

26. A substantially disc-shaped electrode plate (15) arranged for use with a support ring (16) to form an electrode for a plasma reactor, said electrode plate (15) having through holes (3), wherein said electrode plate (15) at a circumference thereof comprises a recess (18) for engaging a flange (17) formed in said support ring (16).

27. A substantially disc-shaped electrode plate (15) arranged for use with a support ring (16) to form an electrode for a plasma reactor, said electrode plate (15) having through holes (3), wherein said electrode plate (15) at a circumference thereof comprises a flange (20) for engaging a recess (19) formed in said support ring (16).
